(19) United States
(12) Patent Application Publication
(10) Pub. No.: US 2017/0338128 A1
(43) Pub. Date: Nov. 23, 2017

(54) MANUFACTURING METHOD OF PACKAGE STRUCTURE

(71) Applicant: Powertech Technology Inc., Hsinchu County (TW)

(72) Inventors: Jen-I Huang, Hsinchu County (TW); Ching-Yang Chen, Hsinchu County (TW)

(73) Assignee: Powertech Technology Inc., Hsinchu County (TW)

(21) Appl. No.: 15/585,160

(22) Filed: May 2, 2017

Related U.S. Application Data
(60) Provisional application No. 62/337,340, filed on May 17, 2016.

(51) Int. Cl. H01L 21/48; H01L 21/56; H01L 23/498

(52) U.S. Cl. CPC H01L 21/4853; H01L 23/49816; H01L 21/486; H01L 21/561; H01L 21/568

(57) ABSTRACT

A manufacturing method of a package structure is provided. The method includes the following steps. A redistribution circuit layer is formed on a first carrier. A die is disposed on the redistribution circuit layer. An encapsulant is formed to encapsulate the die. The first carrier is removed to expose a surface of the redistribution circuit layer. A plurality of recesses are formed on the surface of the redistribution circuit layer. A plurality of conductive terminals are formed corresponding to the recesses on the redistribution circuit layer. Another manufacturing method of a package structure is also provided.

### CROSS REFERENCE TO RELATED APPLICATION

This application claims the priority benefit of U.S. provisional application Ser. No. 62/337,340, filed on May 17, 2016. The entirety of the above-mentioned patent application is hereby incorporated by reference herein and made a part of specification.

### BACKGROUND OF THE INVENTION

### Field of Invention

The present disclosure relates to a manufacturing method, and more particularly, to a manufacturing method of package structure.

### Description of Related Art

Semiconductor package technology has been progressed in recent years in order to develop products with smaller volume, lighter weight, higher integration level and lower manufacturing cost. In certain categories of conventional packaging technologies, taking fan-out wafer level packaging (FO-WLP) for example, a die may be bonded to a carrier substrate by a film and then encapsulated by a molding compound. Moreover, a redistribution layer (RDL) may be formed over the molding compound after encapsulating the die. However, such packaging process may cause the thermal budget issue for the semiconductor component. As such, a packaging process with reduced thermal budget has become a challenge to researchers in the field.

### SUMMARY OF THE INVENTION

The disclosure provides a manufacturing method of a package structure, which reduces the thermal budget and simplifies the packaging process.

The disclosure provides a manufacturing method of a package structure. The method includes the following steps. A redistribution circuit layer is formed on a first carrier. A die is disposed on the redistribution circuit layer. An encapsulant is formed to encapsulate the die. The first carrier is removed to expose a surface of the redistribution circuit layer. A plurality of recesses are formed on the surface of the redistribution circuit layer. A plurality of conductive terminals are formed corresponding to the recesses on the redistribution circuit layer.

The disclosure provides a manufacturing method of a package structure. The method includes the following steps. A redistribution circuit layer is formed on a first carrier. A die is provided on the first carrier and the die electrically connects to the redistribution circuit layer. The die is encapsulated by an encapsulant. The redistribution circuit layer is separated from the first carrier to expose a surface of the redistribution circuit layer. A plurality of conductive pads are formed on the surface of the redistribution circuit layer and a side of each of the conductive pads opposite to the redistribution circuit layer has a recess area. A plurality of conductive terminals are formed on the conductive pads and each of the conductive terminals fills one of the recess areas of the conductive pads, respectively.

Based on the above, the redistribution circuit layer is formed on the first carrier and also the die is disposed on the first carrier and electrically connects the redistribution circuit layer. That is, the redistribution circuit layer is disposed between the first carrier and the die. Therefore, it simplifies the conventional processes of bonding the die on the carrier by the film and removing the film from the die. In addition, since the process of forming the redistribution circuit layer before bonding the die, the thermal budget may be reduced for the package structure. As a result, the reliability of the package structure may be increased.

To make the above features and advantages of the present disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A to FIG. 1I are schematic cross-sectional views illustrating a manufacturing method of a package structure according to an embodiment of the disclosure.

FIG. 2A to FIG. 2C are schematic cross-sectional views illustrating a manufacturing method of a package structure according to an embodiment of the disclosure.

FIG. 3A to FIG. 3F are schematic cross-sectional views illustrating a manufacturing method of a package structure according to an embodiment of the disclosure.

FIG. 4A to FIG. 4C are schematic cross-sectional views illustrating a manufacturing method of a package structure according to an embodiment of the disclosure.

FIG. 5A to FIG. 5J are schematic cross-sectional views illustrating a manufacturing method of a package structure according to an embodiment of the disclosure.

FIG. 6A to FIG. 6C are schematic cross-sectional views illustrating a manufacturing method of a package structure according to an embodiment of the disclosure.

FIG. 7A to FIG. 7F are schematic cross-sectional views illustrating a manufacturing method of a package structure according to an embodiment of the disclosure.

FIG. 8A to FIG. 8C are schematic cross-sectional views illustrating a manufacturing method of a package structure according to an embodiment of the disclosure.

FIG. 9A to FIG. 9D are schematic cross-sectional views illustrating a manufacturing method of a package structure according to an embodiment of the disclosure.

### DESCRIPTION OF EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

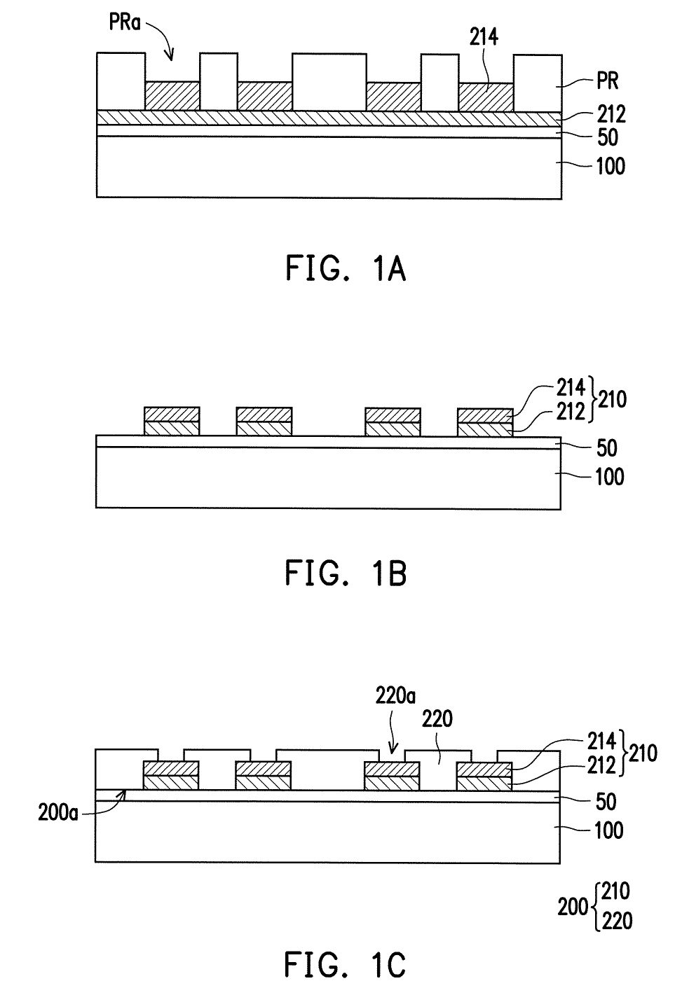

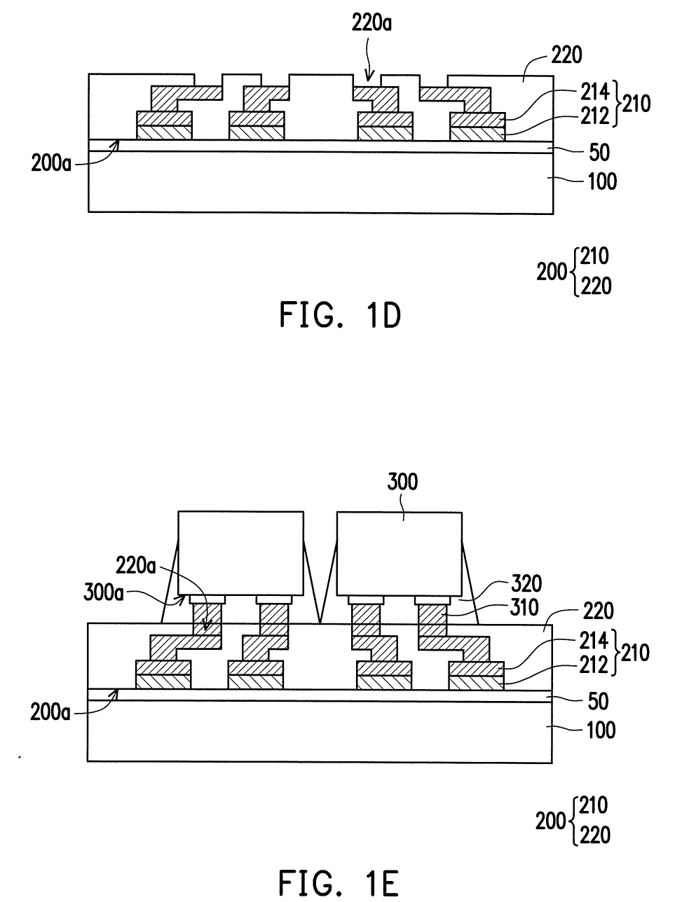

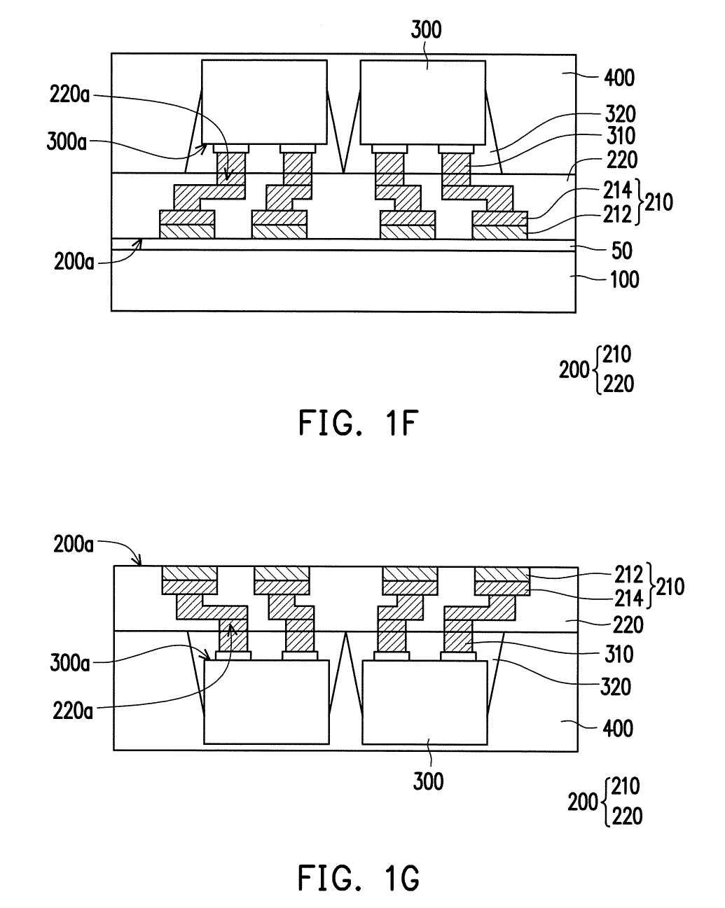

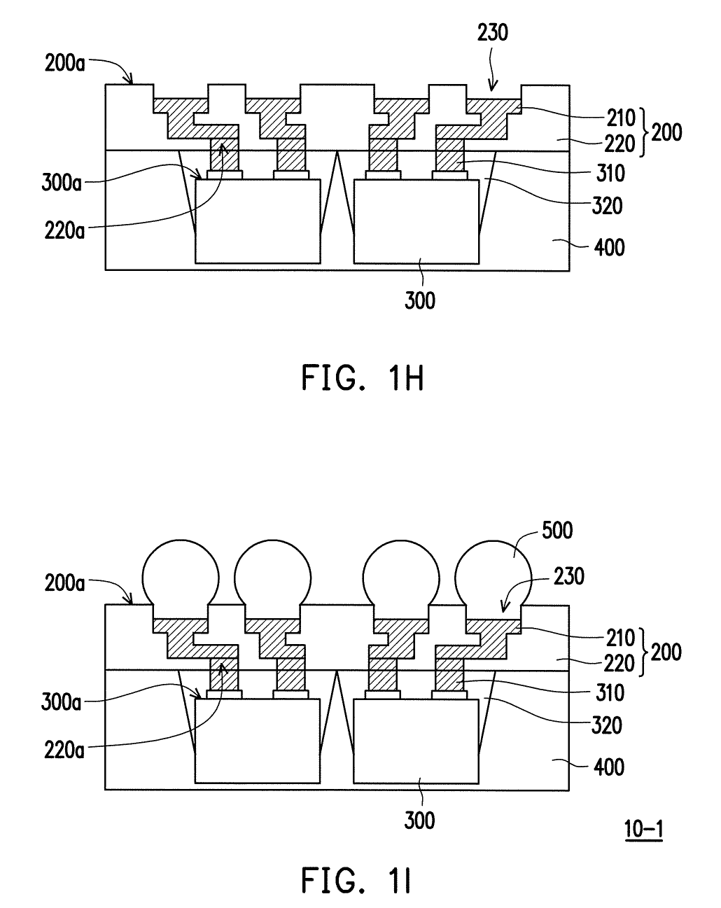

FIG. 1A to FIG. 1I are schematic cross-sectional views illustrating a manufacturing method of a package structure according to a first embodiment of the disclosure. Referring to FIG. 1A to FIG. 1D, a redistribution circuit layer 200 is formed on a first carrier 100. The first carrier 100 may be made of glass, plastic or other suitable materials as long the material is able to withstand the subsequent processes while carrying the package structure formed thereon. The redistribution circuit layer 200 has a surface 200a facing towards the first carrier 100. Moreover, to enhance the releasibility of the redistribution circuit layer 200 from the first carrier 100 in the subsequent process, a de-bonding layer 50 may be formed between the redistribution circuit layer 200 and the first carrier 100. The de-bonding layer 50 may be a LTHC (light to heat conversion) release layer or other suitable release layers. In some embodiments, the surface 200a of the redistribution circuit layer 200 may be in contact with the first carrier 100 directly.

In some embodiments, the redistribution circuit layer 200 includes a patterned conductive layer 210 and a dielectric layer 220. The patterned conductive layer 210 may be embedded in the dielectric layer 220. In addition, the dielectric layer 220 may expose a portion of the patterned conductive layer 210 for further electrical connection purposes. In the present embodiment, the patterned conductive layer 210 is formed before the dielectric layer 220. It should be noted that, in some other embodiments, the dielectric layer 220 may be formed before the patterned conductive layer 210. Further details will be described later in other embodiments. The patterned conductive layer 210 includes a first seed layer 212 and a first metallic layer 214.

As shown in FIG. 1A, the first seed layer 212 may be formed on the first carrier 100. A material of the first seed layer 212 may be copper, gold, nickel, or an alloy thereof, but is not limited thereto. A method of forming the first seed layer 212 may use a physical vapor deposition (PVD) process, an electroless plating process, a chemical plating process, a thermal evaporation process, a sputtering process or other suitable process, but is not limited thereto.

Next, a photoresist PR is formed on the first seed layer 212. The photoresist PR includes a photosensitive resin or other photosensitive materials, but is not limited thereto. The photoresist PR may be a layer formed by coating and further patterned through exposure and development such that a plurality of openings PRa are formed in the photoresist PR for exposing at least a portion of the first seed layer 212. The first metallic layer 214 is formed in the openings PRa of the photoresist PR on the first seed layer 212 through a plating process. The first metallic layer 214 may be formed on the first seed layer 212 exposed by the photoresist PR. The plating process is, for example, electro-plating, electroless-plating, or the like, which is not limited thereto. A material of the first metallic layer 214 may include copper, aluminum, gold, silver, solder or a combination thereof, but is not limited thereto. As shown in FIG. 1B, the photoresist PR may be stripped and the first seed layer 212 exposed by the first metallic layer 214 may be removed using an etching process or other suitable removal process to form the patterned conductive layer 210 as shown in FIG. 1B.

As shown in FIG. 1C, the dielectric layer 220 may be formed on the first carrier 100. The dielectric layer 220 may be formed over the patterned conductive layer 210 and then a portion of the dielectric layer 220 is removed to form a plurality of openings 220a exposing at least the portion of the patterned conductive layer 210. The plurality of openings 220a may be formed through, for example, a photolithography and an etching process. For instance, a material of the dielectric layer 220 may include non-organic or organic dielectric materials such as silicon oxide, silicon nitride, silicon carbide, silicon oxynitride, polyimide, benezocyclobutene (BCB), or the like. In some embodiments, the abovementioned steps may be performed multiple times to obtain a multi-layered redistribution circuit layer as required by the circuit design. The topmost dielectric layer may then have openings exposing at least the portion of the topmost patterned conductive layer. In other words, the redistribution circuit layer 200 may include a plurality of patterned conductive layers 210 and a plurality of dielectric layers 220 stacked alternately.

Referring to FIG. 1E and FIG. 1F, a die 300 is disposed on the first carrier 100 and electrically connects to the redistribution circuit layer 200. The die 300 may be an ASIC (Application-Specific Integrated Circuit). In some other embodiments, other suitable chips or active devices may be utilized as the dies 300. It should be noted that a plurality of dies 300 may be provided in the package and the number of the dies 300 is not limited thereto. Moreover, the die 300 may be disposed on and electrically connected to the redistribution circuit layer 200 through flip-chip bonding. For example, an active surface 300a of the die 300 facing towards the redistribution circuit layer 200 includes a plurality of conductive connectors 310 for electrically connecting to the patterned conductive layer 214 of the redistribution circuit layer 200. The conductive connectors 310 may further include conductive pads (e.g., aluminum pads, copper pads or the like), conductive pillars (e.g. solder pillars, gold pillars, copper pillars or the like), conductive bumps (e.g., reflowed solder bumps, gold bumps, copper bumps or the like) or the combinations thereof. However, it construes no limitation in the disclosure.

Furthermore, an underfill 320 may be formed on the redistribution circuit layer 200 to firmly mount the die 300. For instance, the underfill 320 may be injected or dispensed between the die 300 and the redistribution circuit layer 200 and may also be filled in a gap (not illustrated) between the active surface 300a of the die 300 and the redistribution circuit layer 200 to enhance the attachment there between. The underfill 320 may be epoxy, silicone or the like. Other materials of the underfill 320 may be applicable. In addition, an encapsulant 400 is formed on the redistribution circuit layer 200 to encapsulate the die 300. In some embodiments, the encapsulant 400 may be a molding compound formed by a molding process. In some embodiments, the encapsulant 400 may be an insulating material such as epoxy or other suitable resins.

Referring to FIG. 1G to FIG. 1I, the redistribution circuit layer 200 is separated or de-bonded from the first carrier 100 to expose the surface 200a of the redistribution circuit layer 200. For example, the external energy such as UV laser, visible light or heat, may be applied to the de-bonding layer 50 so that the redistribution circuit layer 200 may be peeled off from the first carrier 100. In some embodiments, the redistribution circuit layer 200 may be directly attached to the first carrier 100, thus, the redistribution circuit layer 200 may be separated from the first carrier 100 through etching or other suitable separation process. Moreover, the redistribution circuit layer 200 may be flipped upside down such that the surface 200a of the redistribution circuit layer 200 faces upward to perform the subsequent processes. It should be noted that the aforementioned flipping step of the redistribution circuit layer 200 is optional depending on the requirement of subsequent processes.

As shown in FIG. 1H, a plurality of recesses 230 may be formed on the surface 200a of the redistribution circuit layer 200 to expose the patterned conductive layer 210. A surface (not illustrated) of the patterned conductive layer 210 opposite to the die 300 and a surface (not illustrated) of dielectric layer 220 opposite to the die 300 may not be coplanar. The redistribution circuit layer 200 may be patterned to form the recesses 230 on the surface 200a of the redistribution circuit layer 200. For example, a portion of the patterned conductive layer 210 is removed through etching or other suitable removal process to form the recesses 230. In the present embodiment, at least a portion of the first seed layer 212 is removed from the redistribution circuit layer 200 to form the recesses 230 as shown in FIG. 1H. The patterned conductive layer 210 may form the bottom surface of the recesses 230. In some embodiments, the dielectric layer 210 or other buffer/passivation layer covering the patterned conductive layer 210 on the surface 200a of the redistribution circuit layer 200 may be patterned to form the recesses 230 exposing at least a portion of the patterned conductive layer 210. The details will be described later in other embodiments.

As shown in FIG. 1I, a plurality of conductive terminals 500 are formed correspondingly on the recesses 230 on the surface 200a of the redistribution circuit layer 200. As such, the conductive terminals 500 may be electrically connected to the die 300 through the patterned conductive layer 210 of the redistribution circuit layer 200. The manufacturing process of a package structure array 10-1 may be substantially completed. In some embodiments, the conductive terminals 500 are solder balls. The conductive terminals 500 may be formed by, for example, a ball placement process, an electroless plating process or other suitable process. The conductive terminals 500 may include conductive pillars, conductive humps or a combination thereof. However, it construes no limitation in the disclosure. Other possible forms and shapes of the conductive terminals 500 may be utilized according to the design requirement. Moreover, a soldering process and a reflowing process are optionally performed for enhancement of the adhesion between the conductive terminals 500 and the redistribution circuit layer 200.

Furthermore, due to the recesses 230 of the redistribution circuit layer 200, the conductive terminals 500 may be correspondingly formed on the recesses 230 to be aligned with the patterned conductive layer 210 exposed by the dielectric layer 220. That is, the steps of forming an alignment mark to form the conductive terminals 500 corresponding to the patterned conductive layer 210 may be omitted. Therefore, the manufacturing processes are simplified and also the reliability of the package structure array is improved. In addition, after separating the first carrier 100 from the redistribution circuit layer 220, portion of the patterned conductive layer 210 is exposed such that the native oxide may be presented on the patterned conductive layer 210 of the surface 220a of the redistribution circuit layer 220. The native oxide may reduce the reliability of package and the processing yield. However, forming the recesses 230 on the surface 220a of the redistribution circuit layer 220 can remove the native oxide present on the patterned conductive layer 210 and avoid the decreased reliability of package resulting from the native oxide issue.

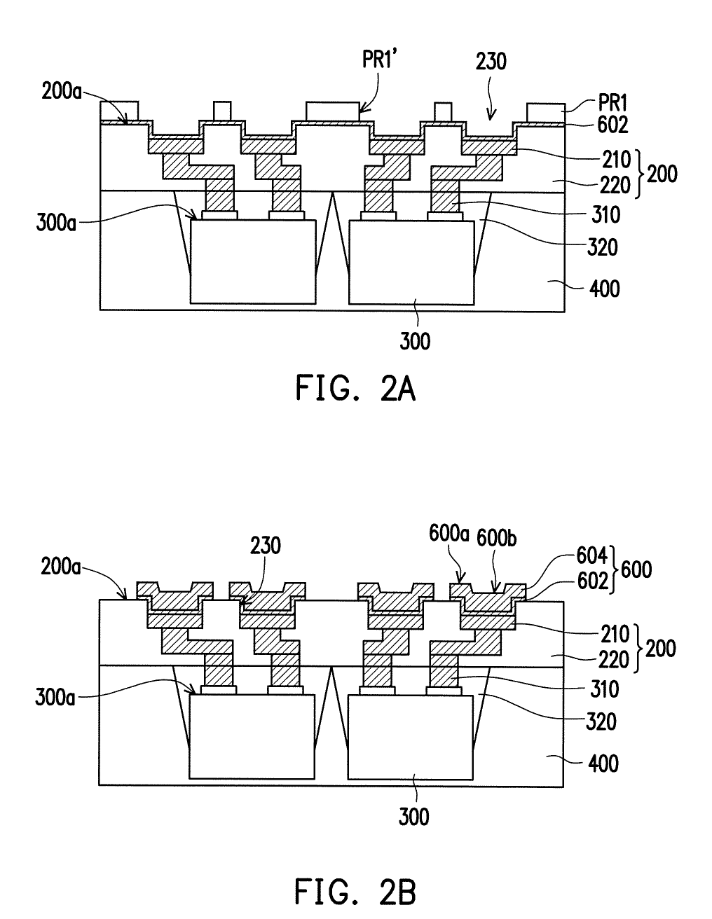

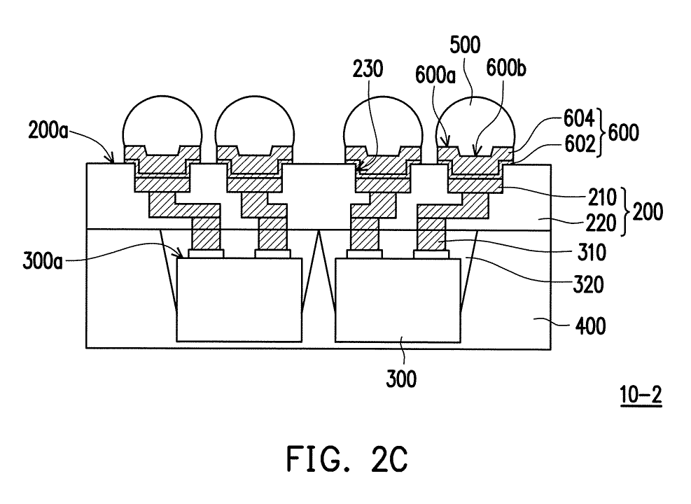

FIG. 2A to FIG. 2C are schematic cross-sectional views illustrating a manufacturing method of a package structure according to an embodiment of the disclosure. The manufacturing method of the present embodiment is similar to the embodiment illustrated in FIG. 1A to FIG. 1I. The difference is, after forming the recesses 230 on the surface 200a of the redistribution circuit layer 200 as shown in FIG. 1H, a plurality of conductive pads 600 are correspondingly formed on the recesses 230 on the surface 200a of the redistribution circuit layer 200.

As shown in FIG. 2A, a second seed layer 602 of the plurality of conductive pads 600 is formed on the surface 200a of the redistribution circuit layer 200 through an electroless plating process, a chemical plating process, a thermal evaporation process, a sputtering process or other suitable process. In addition, the second seed layer 602 covers the dielectric layer 220 and the patterned conductive layer 210 exposed by the dielectric layer 220 on the surface 200a of the redistribution circuit layer 200. A material of the second seed layer 602 may be copper, gold, nickel, or an alloy thereof, but is not limited thereto.

Next, the photoresist PR1 with openings PR1′ is formed on the second seed layer 602 of the plurality of conductive pads 600. The process of forming the photoresist PR1 may be similar as the aforementioned forming process of the photoresist PR and the details is not described thereto. Referring to FIG. 2B, a second metallic layer 604 of the plurality of conductive pads 600 is formed in the openings PR1′ of the photoresist PR1 on the second seed layer 602. The second metallic layer 604 may be formed through an electroless plating process, a chemical plating process or other suitable process. In other words, the second metallic layer 604 is formed on the second seed layer 602 exposed by the photoresist PR1. A material of the second metallic layer 604 may be gold, copper, nickel, an alloy thereof or other conductive materials. The photoresist PR1 may be stripped and the second seed layer 602 not covered by the second metallic layer 604 may also be removed. The process of removal may be performed through etching process or other suitable removal process to form the conductive pads 600. In some embodiments, the conductive pads 600 are referred as under-ball metallurgy (UBM) patterns for ball mount. In addition, a side 600a of each of the conductive pads 600 opposite to the redistribution circuit layer 200 has a recess area 600b. Furthermore, in some embodiment, the area of each of the recesses 230 of the redistribution circuit layer 200 may be greater than the area of each of the recess area 600b of the conductive pads 600.

Referring to FIG. 2C, the conductive terminals 500 are formed on the side 600a of the conductive pads 600. In addition, each of the conductive terminals 500 correspondingly fills one of the recess areas 600b of the conductive pads 600. As such, the conductive terminals 500 are electrically connected to the die 300 through the conductive pads 600 and the patterned conductive layer 210 of the redistribution circuit layer 200. Thereafter, the manufacturing process of a package structure array 10-2 is substantially completed. Since the conductive pads 600 are formed on the redistribution circuit layer 200, the positioning precision and accuracy between the conductive terminals 500 and the redistribution circuit layer 200 may be enhanced. In addition, since each of the conductive pads 600 has the recess area 600b, the electrical connection between the conductive terminals 500 and the conductive pads 600 may be improved. As such, for the high-end device applications, the conductive pads 600 provide an improved electrical connection between the die 300 and the conductive terminals 500.

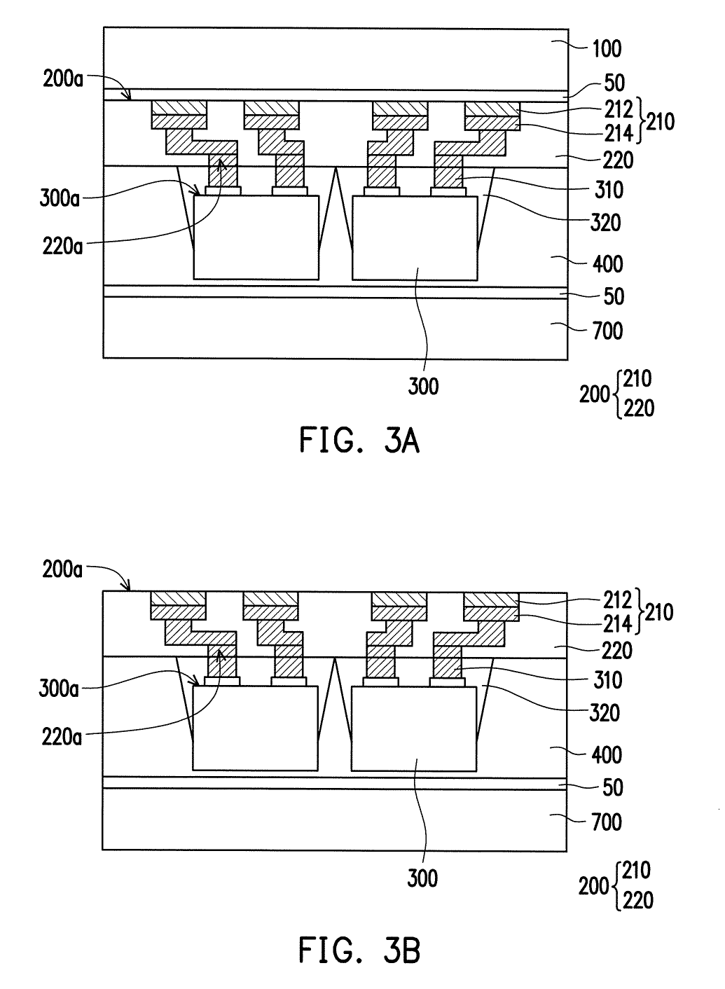

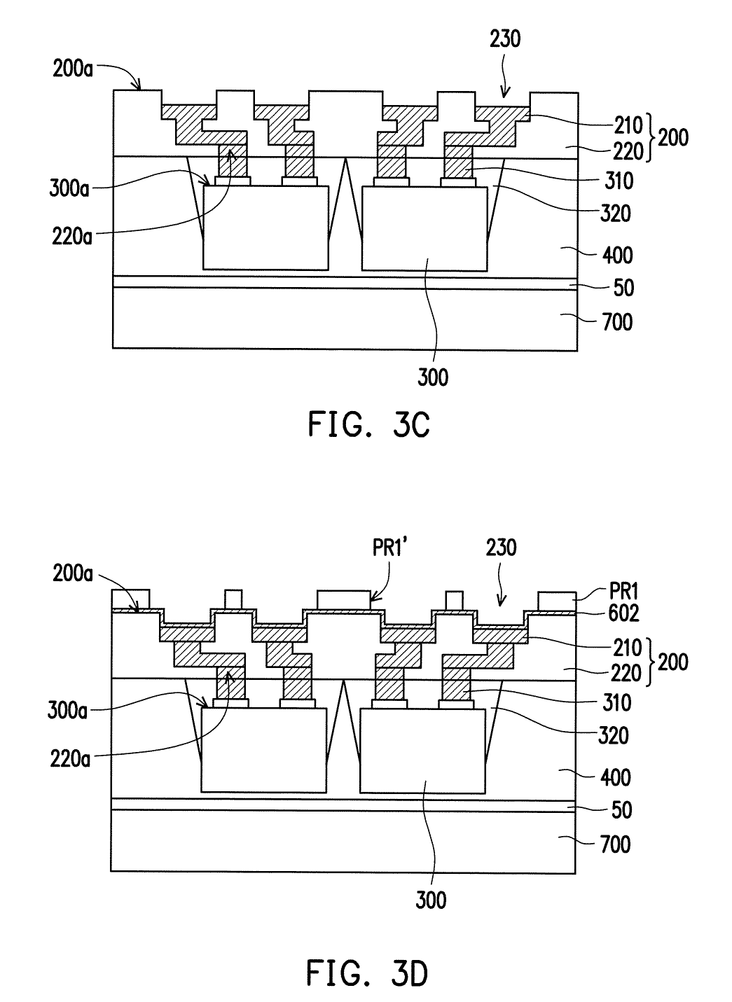

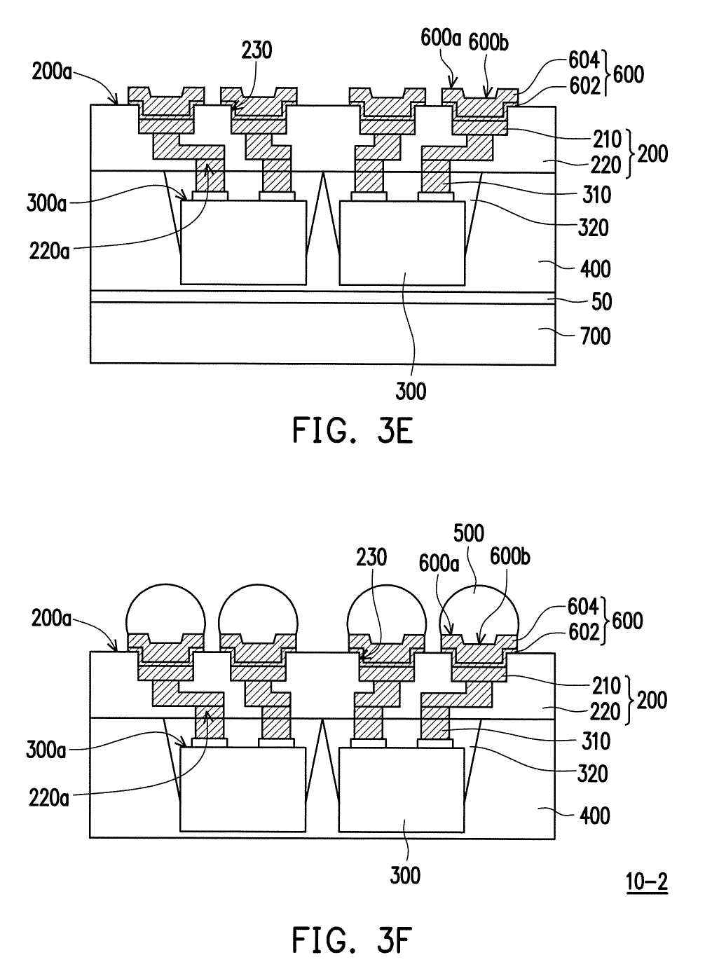

FIG. 3A to FIG. 3F are schematic cross-sectional views illustrating a manufacturing method of a package structure according to an embodiment of the disclosure. The manufacturing method of the present embodiment is similar to the embodiments illustrated in FIG. 1A to FIG. 1H and FIG. 2A to FIG. 2C. The difference to the abovementioned embodiments is, after forming the encapsulant 400 on the redistribution circuit layer 200 to encapsulate the die 300, a second carrier 700 is bonded to the encapsulant 400.

Referring to FIG. 3A, the first carrier 100 and the second carrier 700 are disposed at the two opposite sides of the encapsulant 400. The die 300 is disposed between the first carrier 100 attached to the redistribution circuit layer 200 and the second carrier 700 attached to the encapsulant 400. The material and the bonding process of the second carrier 700 may be the same with or similar to the first carrier 100. As the subsequent processes are performed, the second carrier 700 may be used for the supporting purpose.

Next, referring to FIG. 3B, the first carrier 100 is removed from the redistribution circuit layer 200 and the surface 200a of the redistribution circuit layer 200 is exposed. The subsequent processes illustrated in FIG. 3C to FIG. 3E are similar to the processes illustrated in FIG. 1H, FIG. 2A and FIG. 2B, while the difference lies in that the second carrier 700 is bonded to the encapsulant 400. After forming the conductive terminals 500 on the conductive pads 600, the second carrier 700 may be separated from the encapsulant 400. For example, the external energy such as UV laser, visible light or heat, may be applied to the de-bonding layer 50 so that the second carrier 700 may be removed to expose a surface of the encapsulant 400. Thereafter, the manufacturing process of a package structure array 10-2 is substantially completed as shown in FIG. 3F. In addition, since the second carrier 700 is separated from the encapsulant 400, the overall thickness of the package structure array 10-2 can be reduced. It should be noted that the step of separating process of second carrier 700 may be optional. That is, in some embodiments, a completed package structure array may include the second carrier 700 for supporting the package structure array to the further transferring process, singulation process or other manufacturing processes.

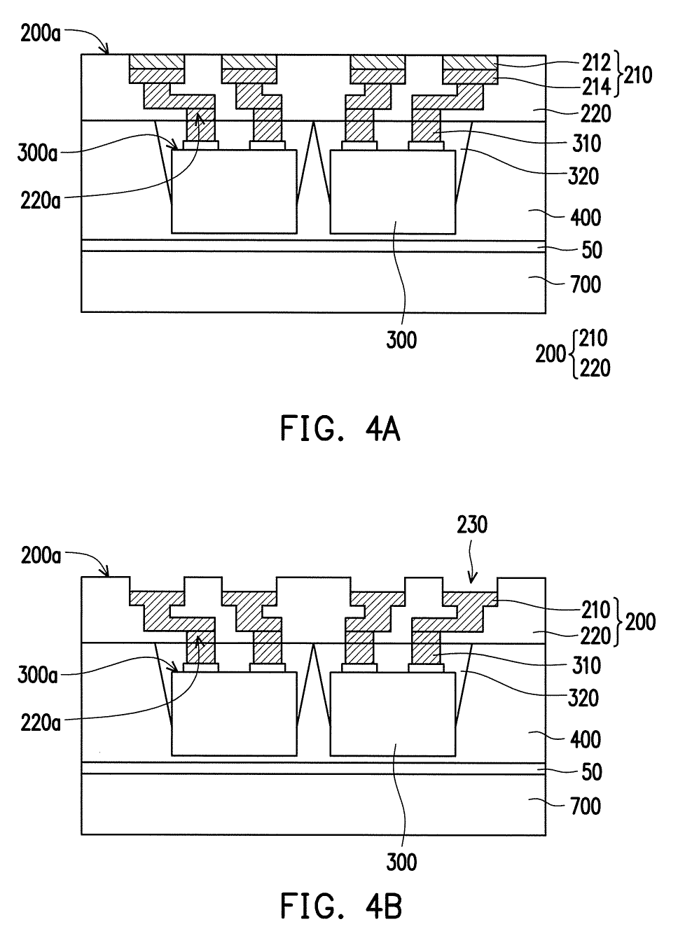

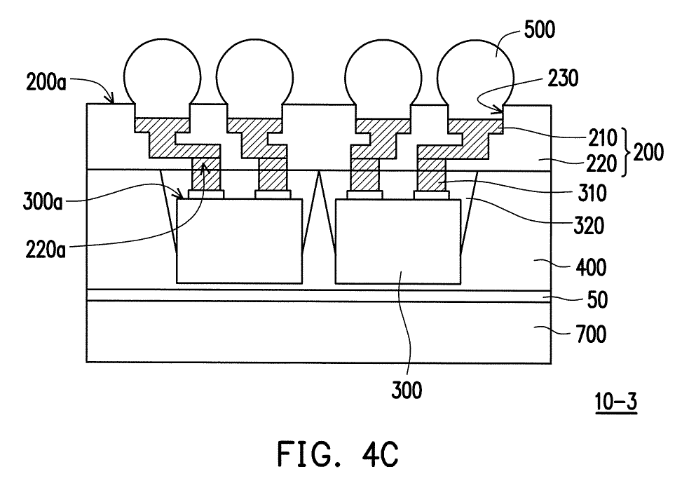

FIG. 4A to FIG. 4C are schematic cross-sectional views illustrating a manufacturing method of a package structure according to an embodiment of the disclosure. The manufacturing method of the present embodiment is similar to the embodiments illustrated in FIG. 1A to FIG. 1I. The difference therebetween is, the manufacturing processes illustrated in FIG. 1G to FIG. 1I are performed while the second carrier 700 is bonded to the encapsulant 400 for supporting purpose. After forming the conductive terminals 500 corresponding to the recesses 230, the manufacturing process of a package structure array 10-3 is substantially completed as shown in FIG. 4C. In some embodiment, the second carrier 700 may be separated from the encapsulant 400 to form a package structure array for reducing the overall thickness of the package structure according to the design requirement.

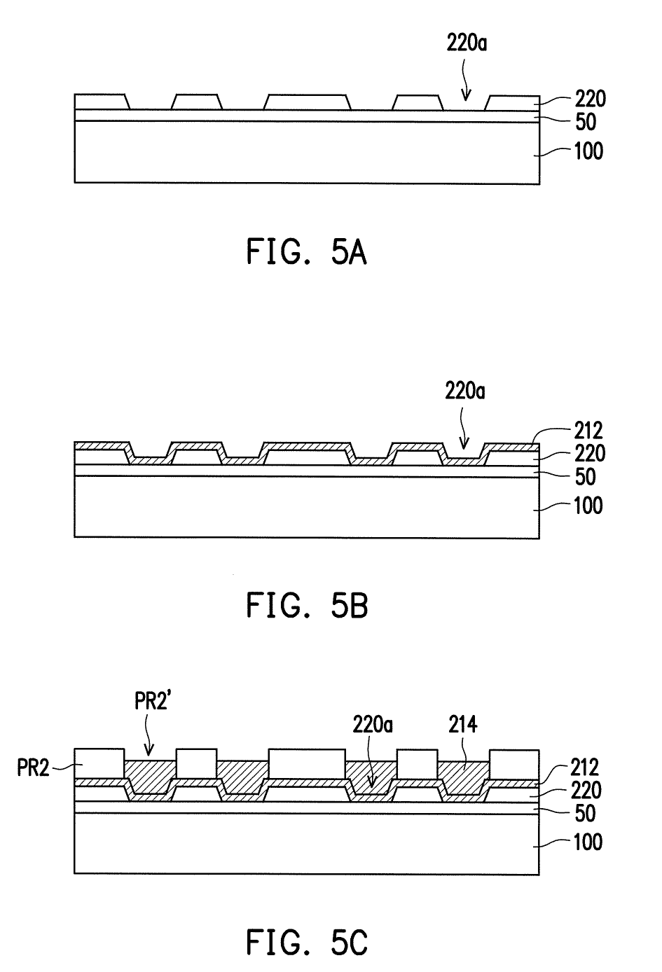

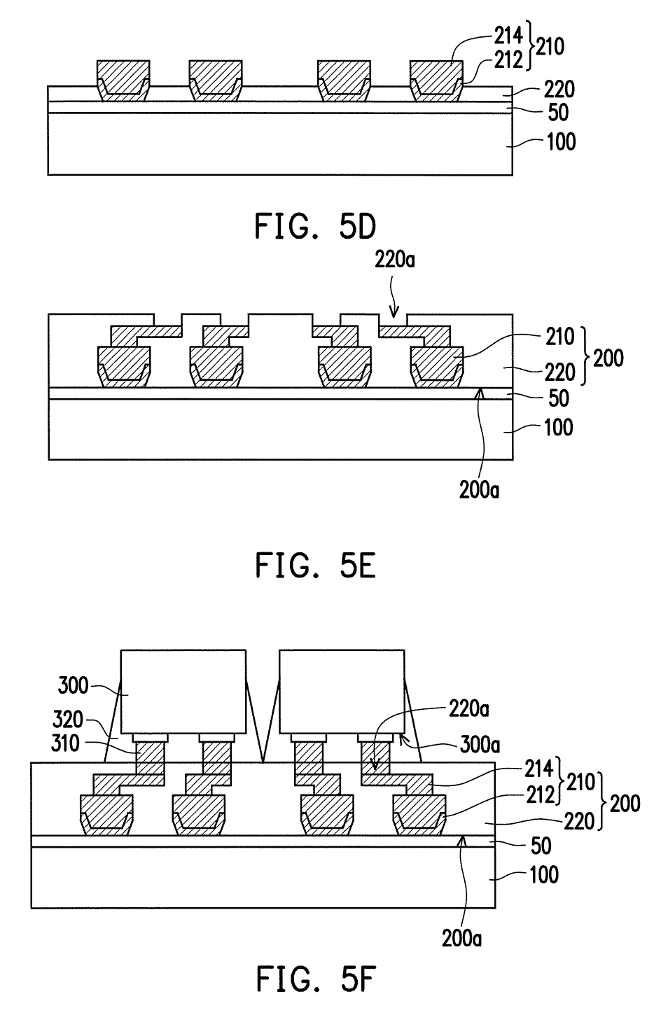

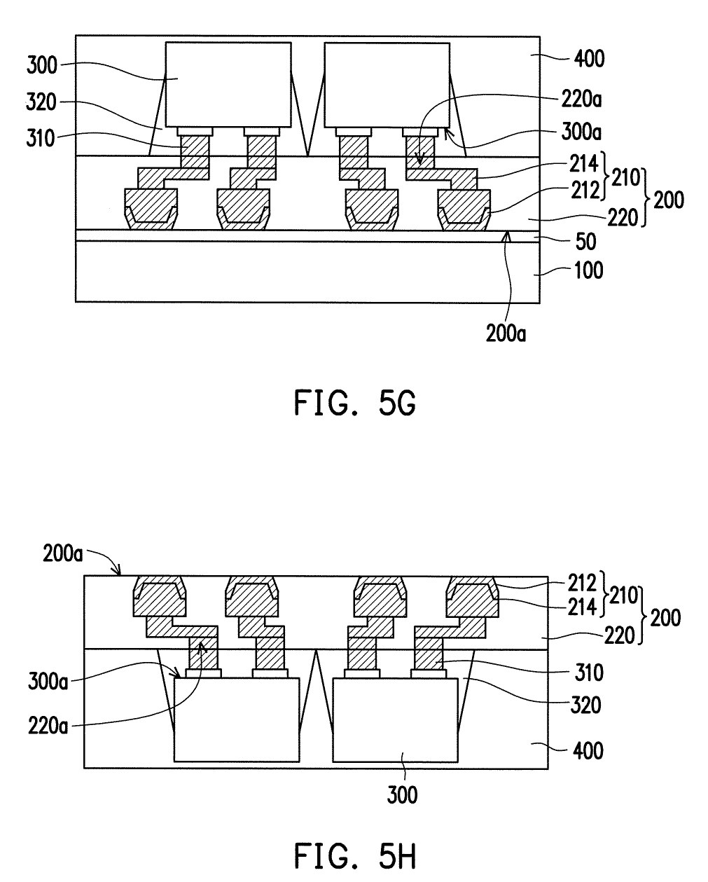

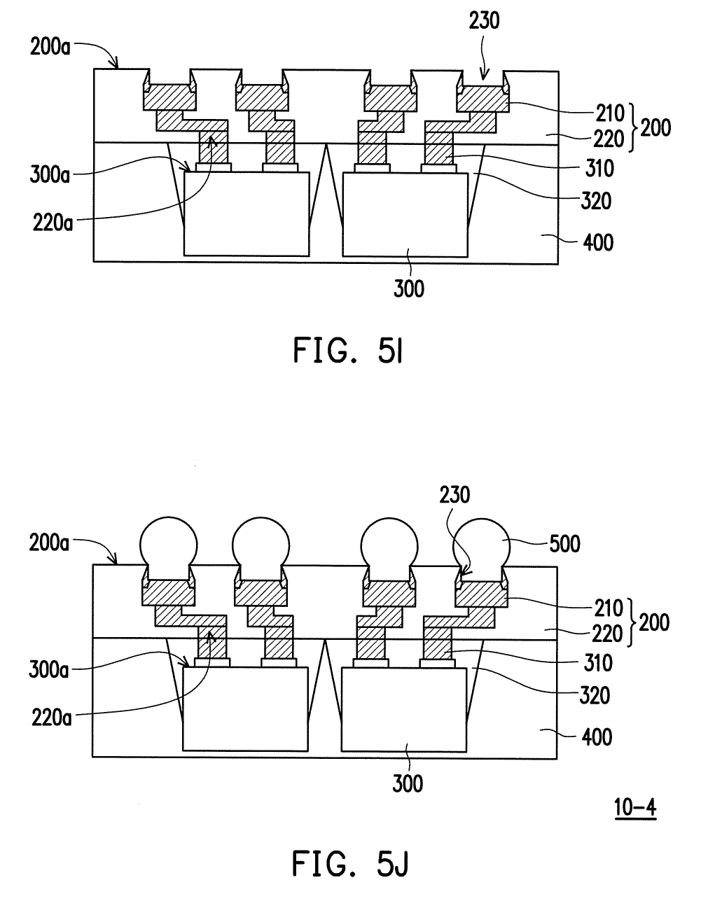

FIG. 5A to FIG. 5J are schematic cross-sectional views illustrating a manufacturing method of a package structure according to an embodiment of the disclosure. In the present embodiment, the dielectric layer 220 is formed before the patterned conductive layer 210. As shown in FIG. 5A, the dielectric layer 220 is formed and patterned on the first carrier 100. That is, the dielectric layer 220 has a plurality of openings 220a as illustrated in FIG. 5A. In some embodiments, the dielectric layer 220 may be patterned to expose the patterned conductive layer 210 after separating the first carrier 100 from the redistribution circuit layer 200.

Next, referring to FIG. 5B, the patterned conductive layer 210 is formed on the dielectric layer 220. The first seed layer 212 of the patterned conductive layer 210 may be formed on the dielectric layer 220 to cover the dielectric layer 220 and the first carrier 100 exposed by the openings 220a of the dielectric layer 220. In some embodiments, the first seed layer 212 may be formed with taper angle between the surface of the first seed layer 212 and the first carrier 100. Referring to FIG. 5C, the photoresist PR2 is formed on the first seed layer 212 covering the dielectric layer 220. The photoresist PR2 has a plurality of openings PR2′ corresponds to the openings 220a of the dielectric layer 220. The photoresist PR2 may be disposed on areas of the dielectric layer 220 other than the openings 220a of the dielectric layer 220. Referring to FIG. 5C, the first metallic layer 214 is formed in the openings PR2′ of the photoresist PR2 disposed on the first seed layer 212. The first metallic layer 214 may be formed through, using an electroless plating process, a chemical plating process or other suitable process. That is, the first metallic layer 214 fills the openings 220a of the dielectric layer 220 and the openings PR2′ of the photoresist PR2. The thickness of the first metallic layer 214 depends on the design requirement. In the present embodiment, a surface of the first metallic layer 214 opposite to the dielectric layer 220 and a surface of the photoresist PR2 opposite to the dielectric layer 220 may not be coplanar. In other embodiment, the surface of the first metallic layer 214 opposite to the dielectric layer 220 and the surface of the photoresist PR2 opposite to the dielectric layer 220 may be coplanar.

Moreover, the photoresist PR2 may be stripped and the first seed layer 212 not covered by the first metallic layer 214 may be removed to form the patterned conductive layer 210 as shown in FIG. 5D. The stripping process may be performed through etching process or other suitable removal process. In some embodiments, the foregoing steps may be performed multiple times to obtain a multi-layered redistribution circuit layer 200 according to the circuit design requirement. After forming the topmost patterned conductive layer 210, the dielectric layer 220 having the openings 220a is formed. In other word, the topmost dielectric layer 220 has the openings 220a exposing at least the portion of the patterned conductive layer 210 as shown in FIG. 5E.

The subsequent processes after the forming of the redistribution layer 200 such as the die bonding process, the die encapsulating process, the first carrier separating process, the recesses forming process and the conductive terminals forming process as illustrated in FIG. 5F to FIG. 5J, respectively, are similar to the processes illustrated in FIG. 1E to FIG. 1I. In some embodiments, after forming the recesses 230 as shown in FIG. 5I, a portion of the first seed layer 212 may remain in the patterned conductive layer 210 such that the first seed layer 212 may become part of the surface of the recesses 230, since the first seed layer 212 may be formed with taper angle between the surface of the first seed layer 212 and the first carrier 100. After forming the conductive terminals 500 on the conductive pads 600, the manufacturing process of a package structure array 10-4 is substantially completed as shown in FIG. 5J.

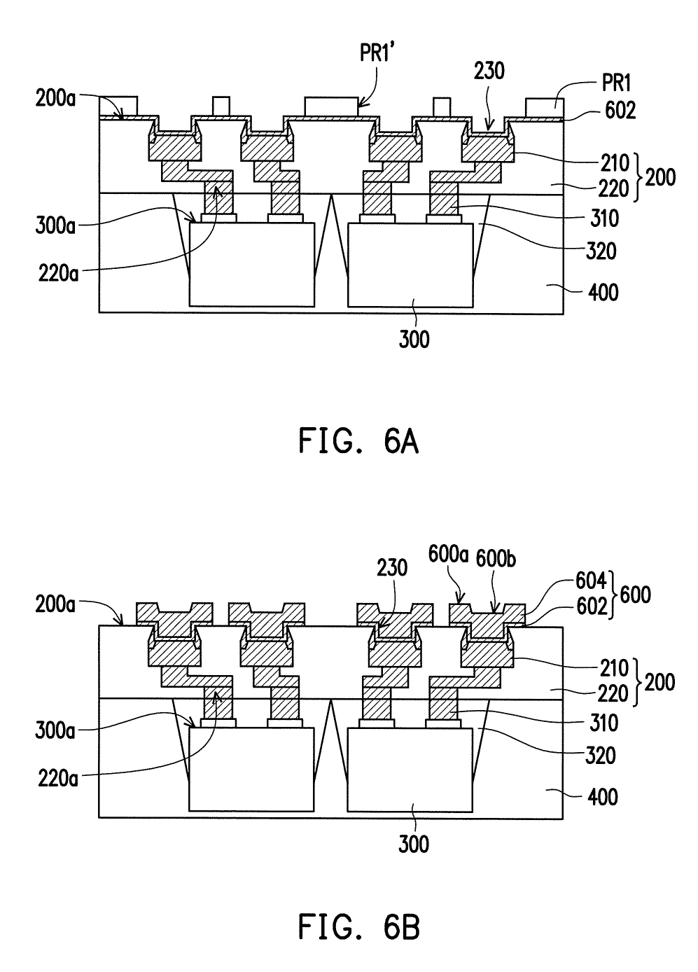

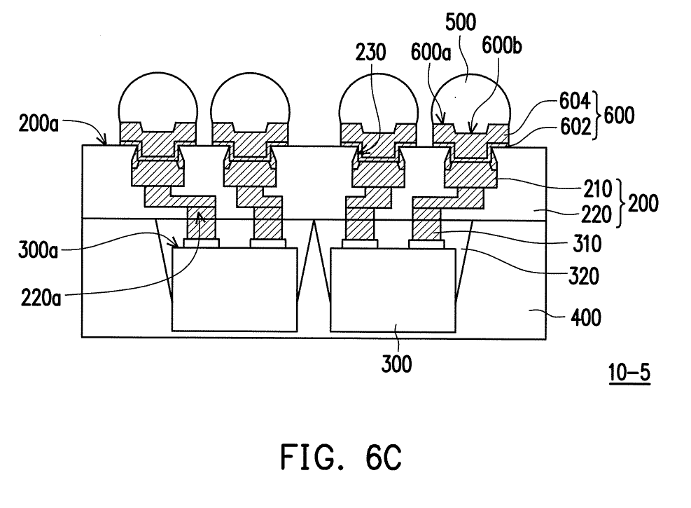

FIG. 6A to FIG. 6C are schematic cross-sectional views illustrating a manufacturing method of a package structure according to an embodiment of the disclosure. The manufacturing method of the present embodiment is similar to the embodiments illustrated in FIG. 5A to FIG. 5J and FIG. 2A to FIG. 2C. Referring to FIG. 6A and FIG. 6B, for example, after forming the recesses 230 on the surface 200a of the redistribution circuit layer 200 as shown in FIG. 5I, the conductive pads 600 are formed on the surface 200a of the redistribution circuit layer 200. Sequentially, the conductive terminals 500 are formed on the conductive pads 600 to complete the manufacturing process of a package structure array 10-5 as shown in FIG. 6C. The processes of forming the conductive pads 600 and conductive terminals 500 are similar to the processes illustrated in FIG. 2A to FIG. 2C, and the details are not described thereto.

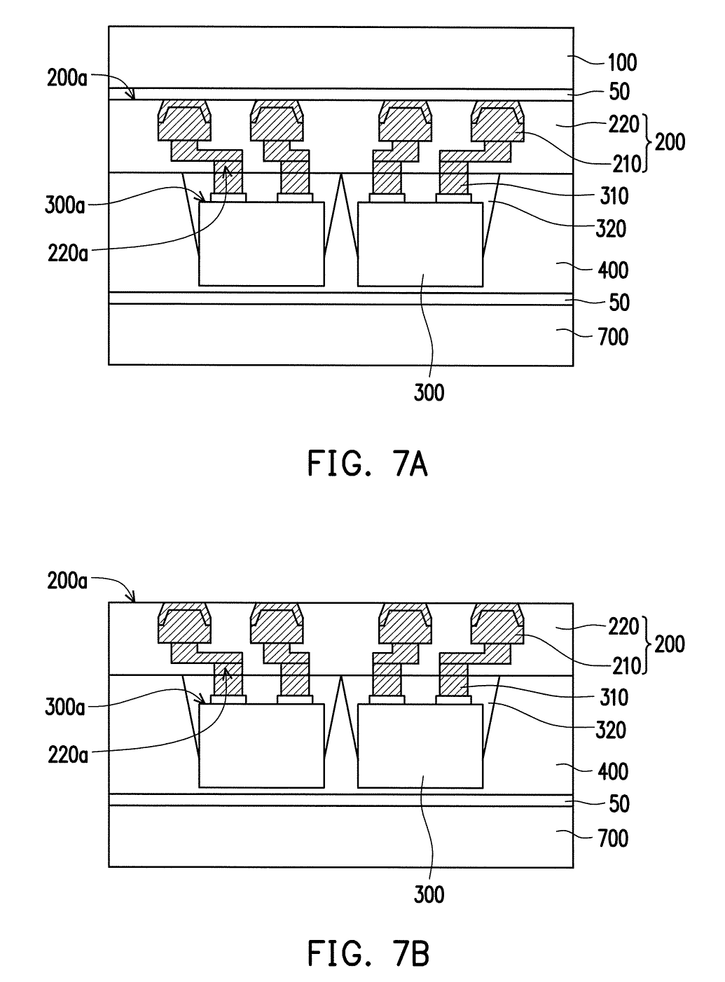

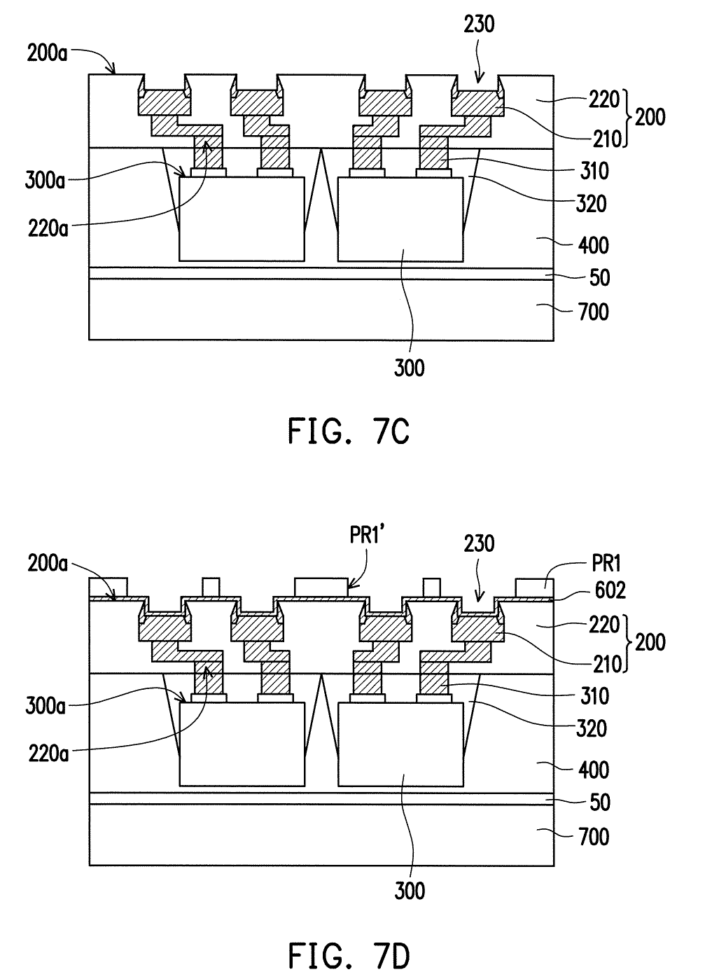

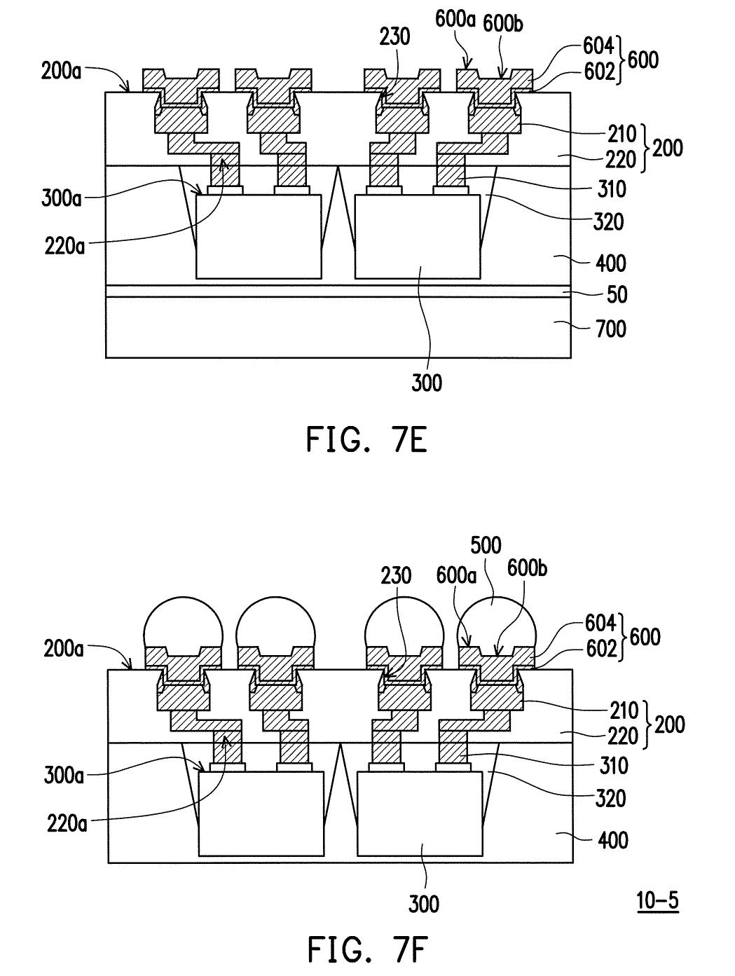

FIG. 7A to FIG. 7F are schematic cross-sectional views illustrating a manufacturing method of a package structure according to an embodiment of the disclosure. The manufacturing method of the present embodiment is similar to the embodiment illustrated in FIG. 6A to FIG. 6C. The difference therebetween is, the manufacturing processes illustrated in FIG. 6A to FIG. 6C are performed while the second carrier 700 is bonded to the encapsulant 400 for supporting purpose. After forming the conductive terminals 500 on the conductive pads 600, the second carrier 700 may be separated from the encapsulant 400. For example, the external energy such as UV laser, visible light or heat, may be applied to the de-bonding layer 50 so that the second carrier 700 may be removed to expose a surface of the encapsulant 400. Thereafter, the manufacturing process of the package structure array 10-5 is substantially completed as shown in FIG. 7F.

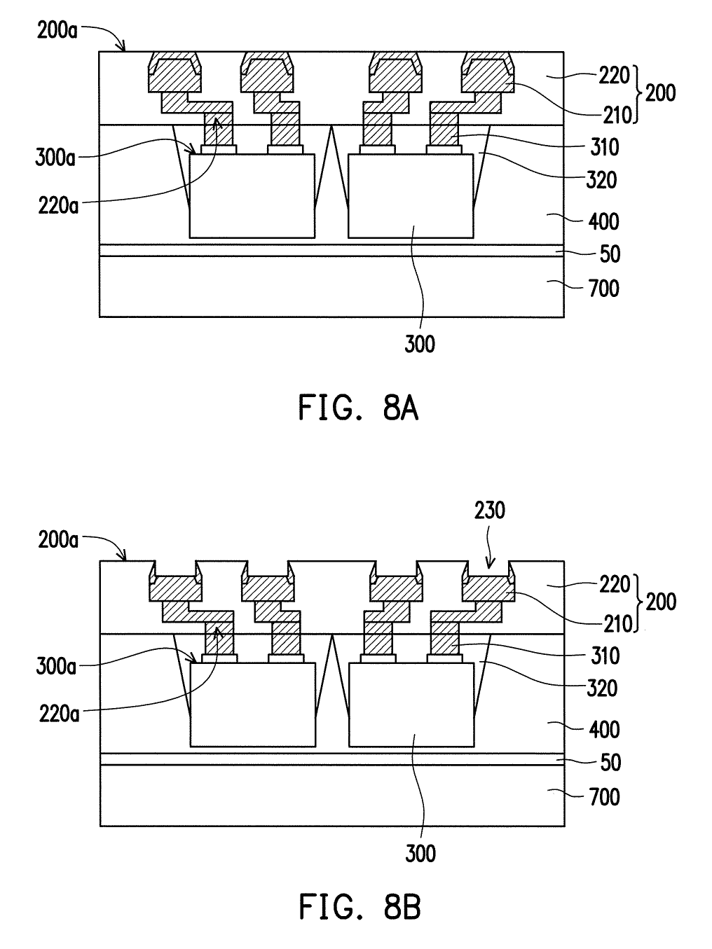

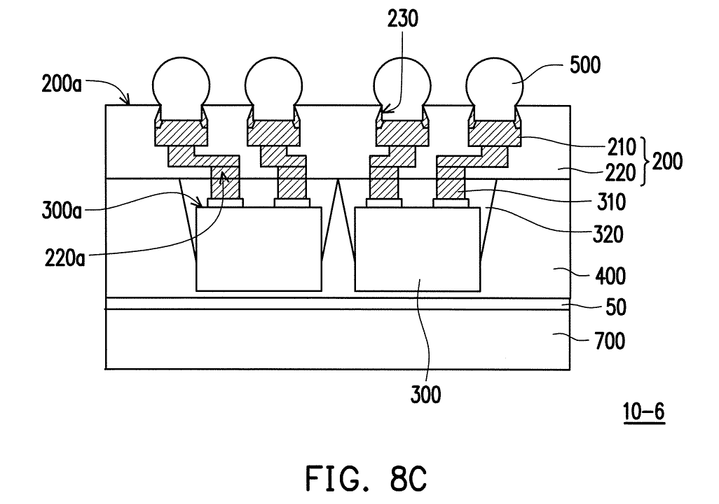

FIG. 8A to FIG. 8C are schematic cross-sectional views illustrating a manufacturing method of a package structure according to an embodiment of the disclosure. The manufacturing method of the present embodiment is similar to the embodiment illustrated in FIG. 7A to FIG. 7F, while in the present embodiment, during forming the recesses 230 as shown in FIG. 8A and FIG. 8B, the second carrier 700 is bonded to the encapsulant 400 for supporting purpose. Next, referring to FIG. 8C, the conductive terminals 500 may be formed on the redistribution circuit layer 200. In addition, each of the conductive terminals 500 can be formed corresponding to one of the recesses 230, respectively. The forming process of the conductive terminals 500 is similar to the process illustrated in FIG. 4C and the details are not described thereto. Thereafter, the manufacturing process of a package structure array 10-6 is substantially completed. It should be noted that in the present embodiment, the package structure array 10-6 includes the second carrier 700 bonded to the encapsulant 400 for supporting purpose. In some embodiment, the second carrier 700 may be separated from the encapsulant 400 to form a package structure array for reducing the overall thickness according to the design requirement.

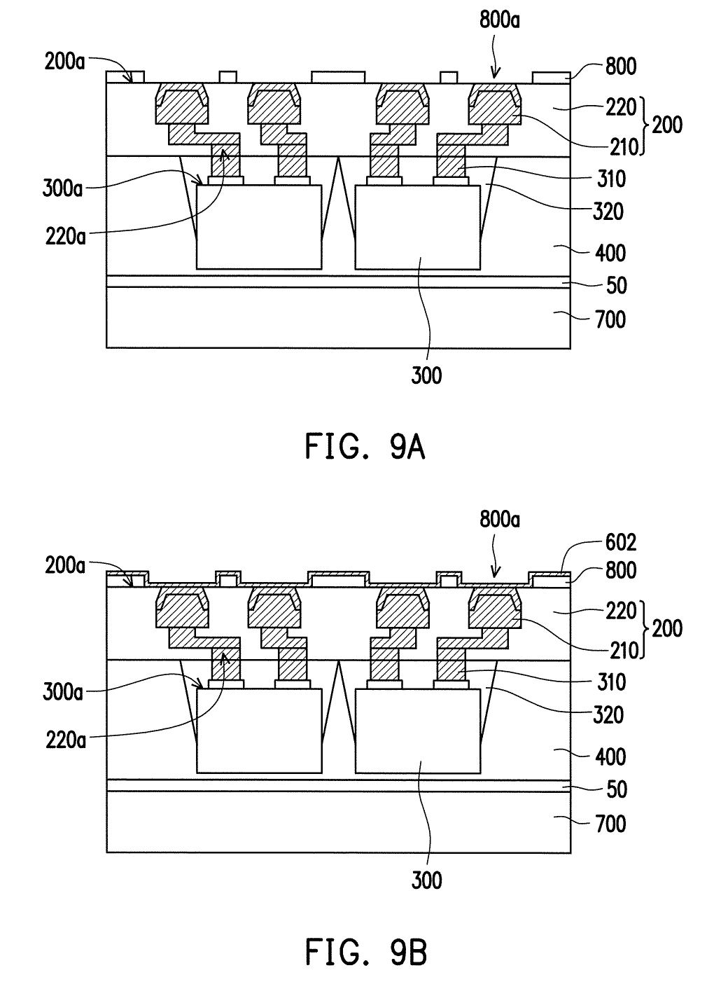

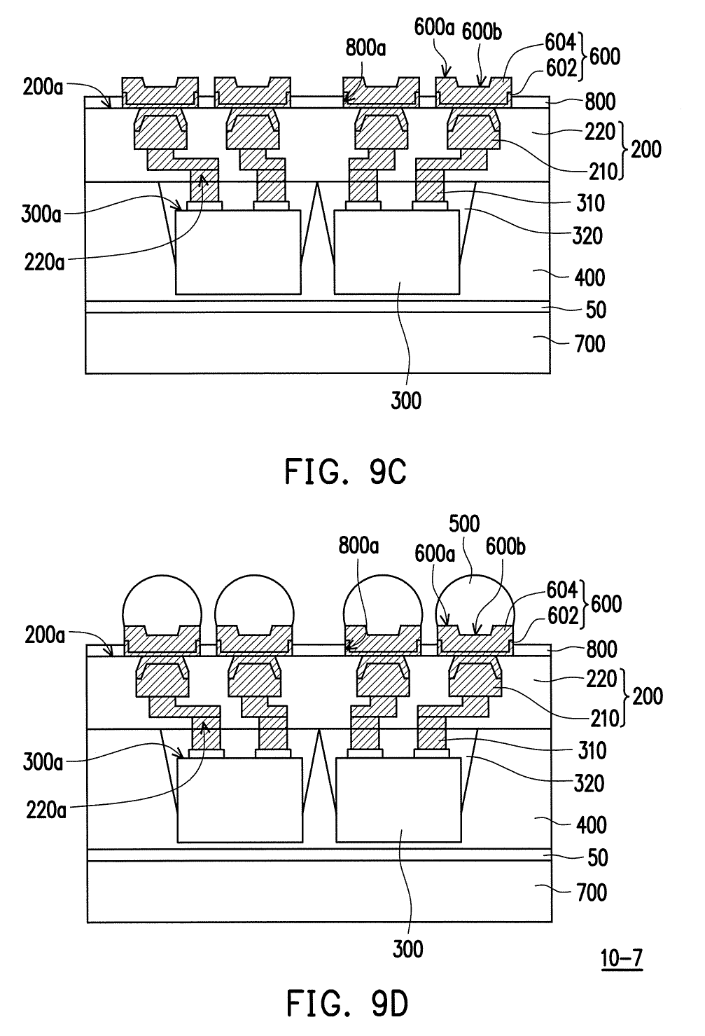

FIG. 9A to FIG. 9D are schematic cross-sectional views illustrating a manufacturing method of a package structure according to an embodiment of the disclosure. The manufacturing method of the present embodiment is similar to the embodiments illustrated in FIG. 7A to FIG. 7F. The difference therebetween is, after separating the first carrier 100 from the redistribution circuit layer 200 to expose the patterned conductive layer 210 of the redistribution circuit layer 200 as illustrated in FIG. 7B, a patterned passivation layer 800 is formed on the surface 200a of the redistribution circuit layer 200 to form a plurality of recesses 800a. Moreover, the recesses 800a of the patterned passivation layer 800 expose at least the portion of the patterned conductive layer 210 of the redistribution circuit layer 200.

Referring to FIG. 9A, a passivation layer may be formed over the redistribution circuit layer 200 and then patterned to form the patterned passivation layer 800 by a photolithography and an etching process, for example. A material of the patterned passivation layer 800 may include polyimide, benzocyclobutene (BCB), polybenzoxazole (PBO) or similar to the material of the aforementioned dielectric layer, which is not limited thereto. Next, referring to FIG. 9B and FIG. 9C, the conductive pads 600 is formed on the surface 200a of the redistribution circuit layer 200 corresponding to the recesses 800a of the patterned passivation layer 800. That is, the conductive pads 600 are formed on the patterned passivation layer 800 and the conductive pads 600 fill the recesses 800a. The forming processes of the conductive pads 600 are similar to the processes illustrated in FIG. 2A to FIG. 2B and the details are not described thereto.

Subsequently, the conductive terminals 500 are formed on the conductive pads 600 and then the second carrier 700 may be separated from the encapsulant 400 to complete the manufacturing process of a package structure array 10-7 as shown in FIG. 9D. The forming process of the conductive terminals 500 is similar to the process illustrated in FIG. 2C and the details are not described thereto. In addition, the separating processes of the second carrier 700 may be similar to the aforementioned process of separating the first carrier 100 from the redistribution circuit layer 200. The details are also not described thereto. It should be noted that the step of separating the second carrier 700 from the encapsulant 400 is optional. In some embodiment, a package structure array may include the second carrier 700 for supporting the package structure array to the further transferring process, singulation process or other manufacturing processes.

Furthermore, in some embodiment, the conductive terminals 500 may be formed on the patterned passivation layer 800 without the conductive pads 600. In addition, the conductive terminals 500 may fill the recesses 800a of the patterned passivation layer 800. For instance, after forming the recesses 800a of the patterned passivation layer 800, each of the conductive terminals 500 are formed corresponding to one of the recesses 800a of the patterned passivation layer 800, respectively. As such, the conductive terminals 500 electrically connect to the patterned conductive layer 210 of the redistribution circuit layer 200. In addition, due to the recesses 800a of the patterned passivation layer 800, the conductive terminals 500 may be positioned and precisely aligned with the patterned conductive layer 210 exposed by the dielectric layer 220 and the patterned passivation layer 800. Therefore, the reliability of the package structure array may be improved.

Based on the foregoing, since forming the redistribution circuit layer is performed before providing the die, the thermal budget may be reduced for the package structure. Moreover, after forming the redistribution circuit layer, the die is disposed on the redistribution circuit layer. That is, the manufacturing steps of forming and releasing a die attach film between the die and the carrier can be omitted, thereby achieving a simplified manufacturing process of the package structure. In addition, since the recesses are formed on the surface of the redistribution circuit layer, the native oxide can be removed and also the conductive terminals can be precisely positioned and aligned with the patterned conductive layer of the redistribution circuit layer. As a result, the improved electrical connection and the reliability of the package structure may be attained. In addition, it may open the possibility to various product designs.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A manufacturing method of a package structure, comprising:
forming a redistribution circuit layer on a first carrier;
disposing a die on the redistribution circuit layer;
forming an encapsulant to encapsulate the die;
removing the first carrier to expose a surface of the redistribution circuit layer;
forming a plurality of recesses on the surface of the redistribution circuit layer; and
forming a plurality of conductive terminals corresponding to the recesses on the redistribution circuit layer.

2. The manufacturing method of a package structure according to claim 1, wherein forming the redistribution circuit layer on the first carrier comprises:
forming a patterned conductive layer on the first carrier before forming a dielectric layer on the first carrier.

3. The manufacturing method of a package structure according to claim 1, wherein forming the redistribution circuit layer on the first carrier comprises:
forming a dielectric layer on the first carrier; and
forming a patterned conductive layer on the dielectric layer.

4. The manufacturing method of a package structure according to claim 1, wherein forming the recesses on the surface of the redistribution circuit layer comprises patterning the redistribution circuit layer.

5. The manufacturing method of a package structure according to claim 1, wherein forming the recesses on the surface of the redistribution circuit layer comprises forming a patterned passivation layer on the surface of the redistribution circuit layer.

6. The manufacturing method of a package structure according to claim 5 further comprising forming a plurality of conductive pads corresponding to the recesses after forming the patterned passivation layer, wherein a side of each of the conductive pads opposite to the redistribution circuit layer has a recess area.

7. The manufacturing method of a package structure according to claim 6, wherein each of the conductive terminals is corresponding to one of the recess areas of the conductive pads respectively.

8. The manufacturing method of a package structure according to claim 1 further comprising:
bonding a second carrier to the encapsulant, wherein the first carrier and the second carrier are disposed at two opposite sides of the encapsulant.

9. The manufacturing method of a package structure according to claim 8, wherein forming the recesses on the surface of the redistribution circuit layer comprises forming a patterned passivation layer on the surface of the redistribution circuit layer.

10. The manufacturing method of a package structure according to claim 8 further comprising:
separating the second carrier from the encapsulant.

11. A manufacturing method of a package structure, comprising:
forming a redistribution circuit layer on a first carrier;
providing a die on the first carrier, wherein the die electrically connects to the redistribution circuit layer;
encapsulating the die by an encapsulant;
separating the redistribution circuit layer from the first carrier to expose a surface of the redistribution circuit layer;
forming a plurality of conductive pads on the surface of the redistribution circuit layer, wherein a side of each of the conductive pads opposite to the redistribution circuit layer has a recess area; and
forming a plurality of conductive terminals on the conductive pads, wherein each of the conductive terminals fills one of the recess areas of the conductive pads respectively.

12. The manufacturing method of a package structure according to claim 11, wherein forming the redistribution circuit layer on the first carrier comprises:
forming a patterned conductive layer on the first carrier before forming a dielectric layer on the first carrier.

13. The manufacturing method of a package structure according to claim 11, wherein forming the redistribution circuit layer on the first carrier comprises:
forming a dielectric layer on the first carrier; and
forming a patterned conductive layer on the dielectric layer.

14. The manufacturing method of a package structure according to claim 11 further comprising:
patterning the redistribution circuit layer to form a plurality of recesses on the surface of the redistribution circuit layer before forming the conductive pads on the surface of the redistribution circuit layer.

15. The manufacturing method of a package structure according to claim 11 further comprising:
bonding a second carrier to the encapsulant, wherein the first carrier and the second carrier are disposed at two opposite sides of the encapsulant.

16. The manufacturing method of a package structure according to claim 15 further comprising:
forming a patterned passivation layer on the surface of the redistribution circuit layer before forming the conductive pads on the surface of the redistribution circuit layer, wherein the patterned passivation layer exposes at least one portion of the redistribution circuit layer.

17. The manufacturing method of a package structure according to claim 16, wherein the conductive pads is formed on the patterned passivation layer.

18. The manufacturing method of a package structure according to claim 16, wherein the conductive pads fill at least the portion of the redistribution circuit layer exposed by the patterned passivation layer.

19. The manufacturing method of a package structure according to claim 15 further comprising:
separating the second carrier from the encapsulant.

20. The manufacturing method of a package structure according to claim 11, wherein providing the die on the first carrier comprises forming an underfill on the redistribution circuit layer.
